(19) United States
(12) Patent Application Publication
(10) Pub. No.: US 2002/0074015 A1
(43) Pub. Date: Jun. 20, 2002

(54) Process for stripping color filter arrays from substrates

(76) Inventor: Thomas J. Grimsley, Fairport, NY (US)

Correspondence Address: Clarence A. Green, Perman & Green, LLP, 425 Post Road, Fairfield, CT, 06430, US

(21) Appl. No.: 09/738,732

(22) Filed: Dec. 15, 2000

(51) Int. Cl. B08B 3/12; B08B 7/04

(52) U.S. Cl. 134/1.3

(57) ABSTRACT

Ozone is used to reduce color filter material, previously deposited on substrates containing electronic sensors, to an ash that can easily be removed by rinsing with water, allowing the substrate to be reused.

### FIELD OF INVENTION

This invention relates to the field of solid-state color imagers and, more particularly, to a process for stripping color filter arrays from substrates employed in such imagers.

### BACKGROUND OF THE INVENTION

High resolution solid-state color imaging devices and methods for making them are well known in the art. Color filter arrays consisting of a lithographically patterned set of colors are fabricated on light-sensing semiconductor substrates enabling the assemblage to sense colors. Color filter array coatings typically comprise dyeable photosensitive coatings, intermediate barrier layers, and non-dyeable photosensitive coatings such as those used for planarizing layers and protective overlayers. More recently color filters have been developed comprising dyed photosensitive polymers and pigmented photosensitive polymers (acrylic compositions).

Conventional processes for preparing a solid-state color image sensing device having color filter arrays include the steps of applying a color filter array to the surface of a silicon-containing wafer substrate having an array of charge-handling semiconductive photosensors and bonding pad areas, exposing the device to an image and developing the coating so as to form a pattern corresponding to the image, and dyeing the exposed and developed image pattern. Subsequently, the steps of coating, exposing the array to an image, developing the pattern of the image, and dyeing the remaining filter elements are repeated, differing only in the image pattern and/or its location and the dye employed, to form sets of color filters, for example, sets containing red, green and blue or cyan, magenta and yellow filter elements or combinations thereof.

The use of dyes is a conventional technique which is still used by some major manufacturers. Newer techniques have been developed which involve direct imaging on a pigmented (or dyed) photosensitive polymer. These pigmented photosensitive polymers are being utilized by flat panel manufacturers to a greater and greater extent and are also supplanting dyed color filters in the sensor segment of the market. Sensors such as pigmented photosensitive acrylic materials require no separate patterning and coloring as the color is in the imagable material.

To achieve high resolution, the color filter elements, however produced, must be in microregistration with the underlying array of photosensors. This means that the filter elements and the photosensor array must be precisely aligned on a micron scale.

Each of the numerous steps involved in the fabrication process affects the quality of the ultimate solid-state color image sensing device. In view of the exacting criticalities involved, the yield of acceptable high quality, high resolution solid-state color image sensing devices is less than 100%. In view of the high costs associated with the manufacture of the substandard substrates, it would be highly desirable to be able to recover substrates from partly or fully fabricated devices so that the substrate could subsequently be used to produce another solid-state color image sensing device.

Thus, the problem facing the art has been to provide a process for stripping color filter array coatings from a substrate of a solid-state color image sensing device so that the substrate can be used to produce another solid-state color image sensing device, which effectively removes all of the coating in a reasonable amount of time, even when the coating has been baked and hardened by various processing steps, and which does not adversely affect the substrate or its electrical properties.

The delicate nature of the sensitive electronic sensors contained in the substrates requires care in the color filter removal process. A wide variety of stripping approaches have been investigated. Prior removal methods may be categorized as either a wet or dry process. Both wet and dry prior art processes worked with previous color filter compositions. However, newer color filter compositions are highly cross-linked polymers that are significantly more difficult to remove than older formulations.

Wet chemical processes for removing the filter material involve solvents, strong acids, strong alkalis and various solvents and are capable of removing the new color filter coatings. However, these processes are typically custom tailored for the particular polymer composition of the color filter to be removed, involve toxic/hazardous solvents or other substances and have the potential of attacking and degrading the performance of the imbedded electronic components.

Dry chemical methods include reactive ion and plasma etching where the substrate is subjected to an oxidizing atmosphere. These methods can remove the filter material but can degrade the performance of the underlying sensors. These processes have the advantage of utilizing non-hazardous reactants and producing non-hazardous byproducts but involve complex and expensive equipment.

A new technique known as downstream plasma etching is capable of removing the new cross-linked polymer filters without damaging the electronic sensors. In this process an oxidizing agent is formed and then brought into contact with the substrate in a non-ionized atmosphere. However, plasma etching is a complex and costly process, etching processes tend to be very time-consuming and, in many cases, leave a residue remaining on the substrate surface even after extended periods of contact time.

Thus, there exists a need for a relatively simply, low cost and environmentally friendly technique for removing the newly developed color filter materials.

### SUMMARY OF THE INVENTION

The present invention provides a process for efficiently stripping color filter arrays from a substrate of a different material.

More specifically, in accordance with the present invention, there is provided a process for stripping a color filter array coating from a substrate of a solid-state color image-sensing device to recover the substrate, which subsequently can be used to produce another solid-state color image sensing device. The process comprises contacting the coated sensor with dry ozone produced by electric discharge and UV radiation for a time effective to completely oxidize the coating and subsequently washing the oxidized coating from the substrate with deionized water.

In a preferred embodiment of the invention, the process comprises the steps of (1) oxidizing the color filter coating on a color image sensing device in a stripping chamber with dry ozone produced by electric discharge and UV radiation, and (2) rinsing the substrate with water, concurrent with the application of sonic energy. With the most recently developed materials, such as pigmented negative acting acrylic polymers, which are significantly harder to remove than conventionally used color filters, it is most preferred to heat the material during the oxidation step.

The process of this invention removes all of the coating in a reasonable amount of time, even when the coating is a highly crosslinked polymer, and does not adversely affect the electrical properties of the device, or the substrate itself.

### DESCRIPTION OF THE PREFERRED EMBODIMENTS

In accordance with this invention, a color filter array coating is removed from a device substrate by contacting the coating with dry ozone produced by electric discharge and UV radiation and washing to remove the oxidized coating. Subsequently, the substrate can be reused to produce another color image sensing device.

As used herein, the term “color filter array coating” is intended to include any or all of the following:

(a) a pigmented or dyeable photosensitive coating that is either undyed or dyed;

(b) intermediate barrier layers; and

(c) non-dyeable photosensitive coatings, for example, those used for planarizing layers and protective overlayers.

The process of this invention is useful with any color filter elements fabricated on substrates. It may be used to remove color filters prepared from either aqueous or solvent-based systems. For example, the process is useful with any of the aqueous-based coatings and substrates disclosed in U.S. Pat. Nos. 4,764,670, 4,355,087 and 4,315,978, the disclosures of which are hereby incorporated by reference in their entirety.

The coating can be formed from materials such as hydrophilic colloids in admixture with a radiation-responsive hardening agent, e.g., dichromated gelatin; diazo resins mixed with a mordant, e.g., those described in U.S. Pat. No. 4,220,700; poly[vinyl alcohols] in admixture with a dichromate and a polymeric mordant; anionic or cationic mordants; or photocrosslinkable mordants. Tpically, the thickness of the dried coating is at least about 0.5 μm and can be greater than 2 μm.

The above-described stripping process is most preferably employed with photoresist coatings manufactured from highly crosslinked negative acting acrylic polymers. In a negative photoresist material, the portion of a layer of the photoresist exposed to an energy source is polymerized, which changes in its chemical character. Polymerization renders the photoresist insoluble with respect to solvents which remove the non-exposed portion of the negative photoresist layer, thereby producing the desired pattern.

In addition, the above-described stripping process is advantageously employed when barrier layers are used in the process for preparing the solid-state color imager. The stripping process is useful with barrier layers (aqueous and non-aqueous) formed from materials known in the art including, for example, nitrocellulose, poly(glycidyl methacrylate), poly(methyl methacrylate), poly(isopropenyl ketone), and polyester ionomers, as described in U.S. Pat. No. 4,315,978. The process is useful with planarizing layers, for example, organic planarizing layers, and with some protective overcoats, for example, those formed from poly(vinyl alcohols).

The process of this invention effectively removes color filter array coatings from any substrate effective for providing a solid-state color image sensing device. Examples of suitable substrates include silicon-containing substrates such as monocrystalline silicon, polycrystalline silicon, silicon dioxide, borosilicate, silicon nitride soda-lime, fused silica, spin-on-glass and the like. Other useful substrates include gallium arsenide.

A substrate which is particularly useful in a solid-state color image sensing device comprises an array of charge-handling semiconductive photosensors and bonding pad areas on a silicon wafer. After the color filter array is formed on the surface of the substrate, electrical contacts are made to the same surface of the substrate through such bonding pad areas. As is well known in the art, the surface of the wafer can also contain other areas such as dicing lines along which the wafer can be cut, areas referred to as guard bands, and so forth. Examples of charge-handling semiconductive photosensors include charge-coupled devices (also known as charge-transfer imagers and the like), charge-injection devices, bucket brigade devices, diode arrays, combinations of these and the like. Useful silicon-containing substrates having photosensitive arrays are described, for example, in U.S. Pat. No. 3,801,884, and are commercially available. In typical devices of this type, the surface often is coated with a protective layer of SiO₂.

In accordance with this invention, a color filter array coating is removed from a device substrate by contacting the coating with dry ozone produced by electric discharge and UV radiation. Subsequently, the substrate can be reused to produce another color image sensing device.

In a particularly preferred technique for practicing this invention, the stripping process comprises the steps of (1) heating the color filter array coating while contacting the heated color filter array with dry ozone generated by electrical discharge and from UV lamps for a time sufficient to reduce the photoresist coating to ash, and (2) subsequently rinsing the substrate with ultrapure water. Excellent results have been obtained even with highly crosslinked acrylic coatings by this technique.

As noted, the present invention is useful in readily removing coatings in both partly and fully fabricated solid-state color image sensing devices. This is so even when the coating or coatings have been hardened by various bakes and processing steps. For example, during processing, the dyed coating may be hardened by baking at a temperature up to about 200° C. for a time up to about one hour. Advantageously, the process has been found to be effective in removing coatings that have been dyed with a variety of dyes known to be useful in preparing solid-state color image sensing devices.

In a preferred embodiment, the coated substrates are placed in a sealable small oven like chamber having a gas input port and an exhaust port. The wafers typically sit on a tray within the unit. The ozone can be generated in the chamber utilizing a UV source and outside the chamber via electrical discharge and piped in. The chamber has a heat source that may be used as desired during the removal process. There are several commercial units available such as those manufactured by companies such as Fusion [now Axcelis Technologies, Rockville, Md.], Samco [532 Weddell Drive, Suite 5, Sunnyvale Calif. 94089], Jelight [2 Mason, Irvine Calif., 92618], and UVOCS [P.O. Box 543, Montgomeryville, Pa. 18936].

While it is possible to remove conventional coatings using ozone produced by either electric discharge or UV radiation, highly cross linked polymeric coatings can be removed in a reasonable time period only by the simultaneous use of a combination of ozone produced by electric discharge and by UV radiation. Ozone is prepared by electrical discharge outside the cleaning chamber and piped into the cleaning chamber. Additional ozone is generated within the chamber utilizing a UV radiation source.

It is desirable to maintain the temperature in the cleaning chamber at or above ambient temperature. Although cleaning will occur at or below ambient temperatures, broadly in the range of from about 0° C. to about 300° C. for the dry ozone process, it is preferred that the temperature be maintained in the range of from about 150° C. to about 300° C. and most preferably in the range of from about 230° C. to about 300° C.

As the temperature increases the residence time in the chamber for the cleaning decreases. So, for example, at temperatures at the lower end of the range, a residence time of up to about 2 hours may be necessary. The amount of time required to effect complete removal of the coating depends, of course, on the particular photoresist material to be removed, the coating thickness, the processing steps to which it has been subjected, etc., and can readily be determined by one of ordinary skill in the art.

Economic considerations and concerns about degrading the substrate make it desirable to limit the cleaning time. Satisfactory results have been obtained with residence times of from about 5 minutes to about 2 hours, preferably from about 5 minutes to about 1 hour and most preferably from about 5 minutes to about 15 minutes.

Following the ozone treatment step, the substrates are subjected to a wash step in deionized water for a period of from about 5 to about 60 minutes, preferably from about 5 to about 30 minutes and most preferably from about 5 to about 15 minutes.

The temperature of the water in the wash bath is in the range of from about 0° C. to about 90° C., preferably from about 25° C. to about 60° C. and most preferably from about 25° C. to about 40° C.

While not essential to achieve the advantageous results, several techniques may be used to enhance the cleaning ability of the wash procedure. The stripping solution can optionally contain additional ingredients, for example, surfactants, wetting agents, stabilizers, etc., so long as they do not adversely affect the resulting stripped substrate. Conventional commercially available cleaning agents or surfactants may be added to the deionized water. Suitable examples include alkaline surfactants such as a product sold as MicroClean; mixtures of hydrogen peroxide/ ammonium hydroxide/water called SC1 Clean in semiconductor industry; deionized water with ammonium hydroxide bubbled through it; and choline (organic alkaline)/surfactant mixtures. In general, most surfactant or alkaline materials will function effectively, either individually or in admixture.

The addition of sonic energy during the wash step facilitates cleaning. The amount of sonic power introduced to the system may be in the range of from about 2 to several hundred watts. The sonic energy may be introduced during the complete wash step but is typically introduced during only a portion of the wash step; in general for from about 2 to about 20 minutes. Sonic energy generators are commercially available from suppliers such as Branson, Verteq [Verteq, Inc. 1241 E. Dyer Rd. Suite 100, Santa Ana, Calif., USA 92705], SubMicron Systems [now Akrion-Allentown Pa.], Crest or FSI [FSI International-Chaska MN].

The following non-limiting example further illustrates the invention.

### EXAMPLE

A red-blue-green 3-color pigmented array using a negative acting photosensitive acrylic polymer produced by Fuji Photo, Inc. was fabricated on a wafer of semiconductor image sensors. The coated substrates were placed on a shelf in the chamber of a Samco ozone stripper. The chamber was closed and the substrate heated to a temperature of 230° C. Ozone produced by electrical discharge by a Samco ozone generator at the rate of 25 g/hr was pumped into the chamber. Concurrently UV radiation provided by a 235 (254 nm & 183 nm discharge) watt UV lamp generated ozone in situ. The substrates were maintained in the chamber for a period of 15 minutes at a temperature of 30° C., after which the substrates were removed from the chamber and placed in a wash solution containing deionized, filtered H₂O containing Microclean additive. The solution is agitated during washing by the introduction of sonic energy produced by a Branson ultrasonic tank operating at 20 kH.

After 5 minutes the substrate was removed from the wash vessel.

A scanning electron micrograph of the substrate confirmed that all vestiges of the coating had been removed.

What is claimed is:

1. A process for removing organic materials from semiconductor substrates comprising contacting the substrates at a temperature of about 0° C. to about 350° C. with dry ozone generated by both electrical discharge and UV radiation.

2. The process of claim 1, wherein the organic material is a color filter material.

3. The process of claim 1, wherein the temperature is in the range of from about 150° C. to about 300° C.

4. A process for stripping a color filter array coating from a substrate of a solid-state color image sensing device to recover the substrate for subsequent use to produce another solid-state color image sensing device, said process comprising placing the substrate in a closed chamber, contacting said color filter array coating with dry ozone for a time effective to remove said coating from said substrate and thereafter washing the substrate with ultrapure water.

5. The process of claim 4 wherein the dry ozone is generated by electrical discharge external and by UV radiation.

6. The process of claim 4 wherein the color filter is a negatively acting highly cross linked acrylic polymer.

7. The process of claim 4 wherein the color filter is contacted with dry ozone for a period of from about 5 minutes to about 2 hours and at a temperature of from about 0° C. to about 350° C.

8. The process of claim 4 wherein the color filter is contacted with dry ozone for a period of from about 5 minutes to about 60 minutes and at a temperature of from about 150° C. to about 300° C.

9. The process of claim 4 wherein the color filter is contacted with dry ozone for a period of from about 5 minutes to about 20 minutes and at a temperature of from about 230° C. to about 300° C.

10. The process of claim 4 wherein the substrate is washed for a period of time sufficient to remove the coating residue from the substrate.

11. The process of claim 4 wherein the substrate is washed for a period of from about 5 to about 60 minutes at a temperature of from about 0° C. to about 90° C.

12. The process of claim 4 wherein the substrate is washed for a period of from about 5 to about 30 minutes at a temperature of from about 25° C. to about 60° C.

13. The process of claim 4 wherein the substrate is washed for a period of from about 5 to about 15 minutes at a temperature of from about 25° C. to about 40° C.

14. The process of claim 4 wherein the substrate is agitated during the wash step by the application of sonic energy.
